(19) United States
(12) Patent Application Publication
(10) Pub. No.: US 2003/0077883 A1
(43) Pub. Date: Apr. 24, 2003

(54) Deposition method, deposition apparatus, and semiconductor device

(76) Inventor: Naoto Ohtake, Tokyo (JP)

Correspondence Address: LORUSSO & LOUD, 3137 Mount Vernon Avenue, Alexandria, VA, 22305, US

(21) Appl. No.: 10/230,406

(22) Filed: Aug. 29, 2002

(30) Foreign Application Priority Data
Sep. 7, 2001 (JP) 2001-272617
Jul. 9, 2002 (JP) 2002-200451

(51) Int. Cl. C30B 1/00; H01L 21/20; H01L 21/36

(52) U.S. Cl. 438/478

(57) ABSTRACT

To provide a deposition method and a deposition apparatus, in which deposition can be performed under a low temperature and a substrate does not suffer from charge-up damage, and a semiconductor device produced thereby.

The deposition method is that reactive gas is made to pass through communication holes and guided toward downstream of the communication holes after the gas is exposed to surface wave of microwave, and it is reacted with silicon compound gas to deposit a silicon-containing film on a substrate arranged in the downstream.

### BACKGROUND OF THE INVENTION

1. Field of the Invention

The present invention relates to a deposition method, a deposition apparatus, and a semiconductor device. More particularly, the present invention relates to a technology useful for depositing a silicon containing film at a low temperature while restricting charge-up of a substrate.

2. Description of the Related Art

Using a film obtained by thermal reaction between tetraethoxysilane (Si(OC₂H₅)₄) and ozone (O₃) for an interlayer insulating film is an important process even at the present day when a low dielectric constant film is about to be introduced in a high-speed random logic. The reason why the film is not going to be replaced by the low dielectric constant film is that step coverage of the film obtained in a reaction system of tetraethoxysilane/ozone is good. However, the deposition temperature of this reaction system is as high as over 400° C., causing a hillock in the underlying metal film to create a problem of low yield. Though the film may be deposited under a lower temperature in an effort to restrict hillock, there occurs a problem that deposition rate drastically reduces and it results in reduction of throughput of an apparatus.

On the other hand, in the low dielectric constant insulating film whose introduction has progressed, a film harder than the low dielectric constant insulating film is required, either as a mask for etching or an etching stopper. A silicon oxide film formed by thermal reaction between monosilane and oxidizing agent is used for this film. Where an low dielectric insulating film is formed in lower layers, high temperature deposition conditions cannot be used because the low dielectric constant insulating film has a problem in heat resistance. For this reason, deposition is performed under the low temperature of 200° C. in this case, which cannot obtain the required hard film.

The silicon oxide film may be formed thicker to compensate for insufficient hardness. However, there occurs a problem that it lengthens deposition time, which leads to reduction of throughput. Furthermore, where the thicker silicon oxide film is leaved between the low dielectric insulating films, the problem arises that the dielectric constant of the entire insulating film increases.

Incidentally, a deposition method using plasma can give solution to the low deposition temperature and hardening of the film, which are required in the foregoing two examples.

However, plasma generated in conventional systems produces a new problem that ions or the like having high energy state reach the surface of a wafer, generating a large amount of secondary electrons when they impact on the wafer, thus the wafer suffers from charge-up damage.

Particularly, in the case where long wirings are formed on the wafer, there occurs another problem that antenna effect causes gate breakage, which reduces yield.

There exists a remote plasma apparatus for the conventional deposition apparatus using plasma. In this apparatus, ions cannot completely be removed in some cases and, in addition, uniformity of dissociated excitation species is poor, leading to the aforementioned problem of charge-up damage.

### SUMMARY OF THE INVENTION

The object of the present invention is to provide a deposition method and a deposition apparatus, in which deposition can be performed at a low temperature and a substrate does not suffer from charge-up damage, and a semiconductor device produced thereby.

The foregoing problems are solved by a deposition method comprising: after exposing a reactive gas to a surface wave of a microwave, guiding the reactive gas to a downstream of a communication hole by making the reactive gas to pass through the communication hole, and making the reactive gas to react with a silicon compound gas at the downstream to form a silicon-containing film on a substrate arranged at the downstream.

According to this method, the reactive gas is exposed to the surface wave of the microwave to be excited, and surface wave plasma of the reactive gas is generated. The surface wave plasma has such a characteristic that its electron density rapidly attenuates toward downstream. Due to this characteristic, although reactive gas molecules dissociate and atomic reactive gas can be generated, charged particles rarely remain in the downstream, despite that the atomic reactive gas survives. In the present invention, the reactive gas is made to pass through the communication holes in the downstream in order to remove the charged particles that are still remain in the downstream. It has been made clear that by making the gas pass through the communication holes, the atomic reactive gas required for reaction was guided on the substrate while the charged particles were approximately completely removed.

Since heat is not used to generate the atomic reactive gas, deposition is performed under a lower temperature than the case where deposition is performed by thermal reaction. Moreover, since the charged particles are approximately completely removed, the substrate is not charged up by the charged particles unlike a conventional deposition method using plasma.

In addition, it has been found out that the energy of the atomic reactive gas was decreased to near the ground state. Because the energy decreases, the secondary electrons that can be generated when the atomic reactive gas of high energy reaches the substrate are reduced, and thus the substrate becomes harder to be charged up.

Further, it is preferable to introduce the microwave onto one surface of a dielectric window to generate the surface wave of the microwave. In this case, the surface wave generates in the vicinity of the other surface of the dielectric window.

One example of microwave frequency is 2.45 GHz. When this frequency is used, it is required that the electron density of the reactive gas in the vicinity of the surface wave be larger than 7.6×10¹⁶ m⁻³. If the density is smaller than this value, the microwave goes into the downstream and the surface wave is not generated.

On the other hand, it is preferable to use each of a plurality of openings that are formed in a gas dispersion plate as the communication hole through which the reactive gas passes.

The silicon-containing film is deposited, for example, by setting the pressure of atmosphere, which contains the reactive gas and the silicon compound gas, in the downstream to about 13.3 to 1330 pascal (Pa), and by arranging the gas dispersion plate at a distance of about 5 to 20 cm from the other surface of the dielectric window in a downstream direction.

It has been found out that when oxygen (O₂) is used with nitrogen (N₂), dissociation of oxygen (O₂) is promoted by nitrogen (N₂), and thus the deposition is promoted.

Furthermore, even when a wiring layer and a gate insulating film of a MOS transistor are formed on the substrate in advance before depositing the silicon-containing film, the wiring layer is not charged up, hence the gate insulating film is prevented from being broken. Moreover, occurrence of hillock on the wiring layer is prevented because the deposition temperature is low.

A semiconductor substrate or a glass substrate is used as the substrate. Among these substrates, the glass substrate requires deposition process under a low temperature because it is vulnerable to heat. Accordingly, the present invention, allowing the low temperature deposition, is preferably applied for the glass substrate as well.

Further, the foregoing problems are solved by a deposition apparatus that comprises: a dielectric window having two principal surfaces, where a microwave being introduced onto one of the two principal surfaces; a gas dispersion plate that is provided at a distance from other principal surface of the dielectric window and has a plurality of communication holes; a substrate holder provided in downstream of the gas dispersion plate; a reactive gas supply port that is in communication with a space between the substrate holder and the other principal surface of the dielectric window; and a silicon compound gas supply port that is in communication with the space.

In this apparatus, the surface wave of the microwave generates in the vicinity of the other surface of the dielectric window. The reactive gas, supplied from the reactive gas supply port, is excited by the surface wave, generating a surface plasma of the reactive gas. Since the gas dispersion plate is provided at the downstream where the electron density of surface wave plasma has attenuated, its material does not scatter due to collision with the charged particles having large kinetic energy nor suffer from damage due to heating by plasma.

Further, a plurality of communication holes are formed in the gas dispersion plate. When the reactive gas passes through the communication holes, the charged particles are removed and the energy of the atomic reactive gas is lowered, and thus the substrate on the substrate holder is not charged up. In addition, the apparatus does not generate the atomic reactive gas by thermal decomposition but generates by the surface wave of the microwave, deposition is performed under a lower temperature than the case of the thermal decomposition.

Furthermore, it is preferable that the reactive gas supply port is in communication with upstream of the gas dispersion plate, and the silicon compound gas supply port is in communication with the downstream of the gas dispersion plate. With this configuration, the reactive gas and the silicon compound gas react with each other in the downstream of the gas dispersion plate but do not react in the upstream of the gas dispersion plate, so that such an inconvenience does not arise that reaction product deposits on the gas dispersion plate.

The gas dispersion plate is provided, for example, at a distance of about 5 to 20 cm from the other surface of the dielectric window in a downstream direction.

### BRIEF DESCRIPTION OF THE DRAWINGS

FIG. 1 shows a cross-sectional view of a deposition apparatus according to an embodiment of the present invention;

FIG. 2 shows is a plan view of a showerhead used in the deposition apparatus according to the embodiment of the present invention;

FIG. 3 shows a graph showing attenuation characteristics of the electron density of surface wave plasma, which is generated by the deposition apparatus according to the embodiment of the present invention, in a downstream direction;

FIG. 4 shows a cross-sectional view showing another introduction method of the microwave that is applicable for the deposition apparatus according to the embodiment of the present invention; and

FIGS. 5A to 5C show a cross-sectional view for explaining an example of the present invention.

### DESCRIPTION OF THE PREFERRED EMBODIMENTS

Embodiments of the present invention will be described in detail as follows with reference to the accompanying drawings.

(1) Description of the deposition apparatus according to the embodiments of the present invention

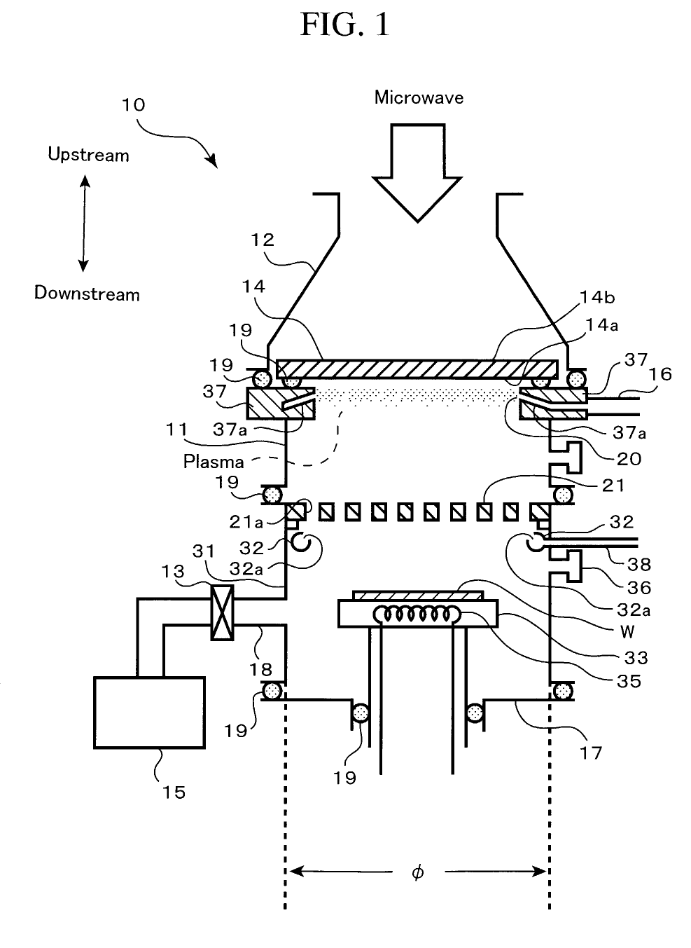

FIG. 1 is the cross-sectional view showing the deposition apparatus according to this embodiment.

As shown in the drawing, the deposition apparatus 10 comprises a waveguide 12, a plasma chamber housing 11, a reaction chamber housing 31, and a base 17, in sequence from the upstream. Sealing member 19 such as an o-ring and a gasket are inserted between these components to keep the inside of the apparatus 10 in an airtight condition. The plasma chamber housing 11 and the reaction chamber housing 31 are in an approximate cylindrical shape and its diameter φ is about 240 cm. The diameter is not limited to this value and may be designed in a desired value.

As shown in the drawing, the waveguide 12 has a tapered shape, and a dielectric window 14 is arranged near the larger opening end of the waveguide 12. The dielectric window 14 is preferably formed of quarts, alumina (Al₂O₃), aluminum nitride, or the like.

Ring-shaped member 37 is provided at the downstream of the dielectric window 14. The sealing member 19 similar to the one described above is inserted between the dielectric window 14 and the ring-shaped member 37.

A pocket 37a, which communicates with the inside of the plasma chamber housing 11 and a reactive gas supply port 16, is engraved to the ring-shaped member 37 integrally. The opening end of the pocket 37a, which appears on the inner surface of the plasma chamber housing 11, is a slit 20 from which the reactive gas is supplied into the plasma chamber housing 11. As shown, the pocket 37a is tilted upward. By appropriately selecting a tilt angle, the surface wave can be generated strongly to efficiently excite the reactive gas, or the uniformity of excitation species of the reactive gas can be improved.

A supply method of the reactive gas is not limited to the above. Although the pocket 37a is integrally formed in a ring-shaped manner, a plurality of opening portions, which communicate with the reactive gas supply port 16, may be alternatively provided at a predetermined distance in the ring-shaped member 37.

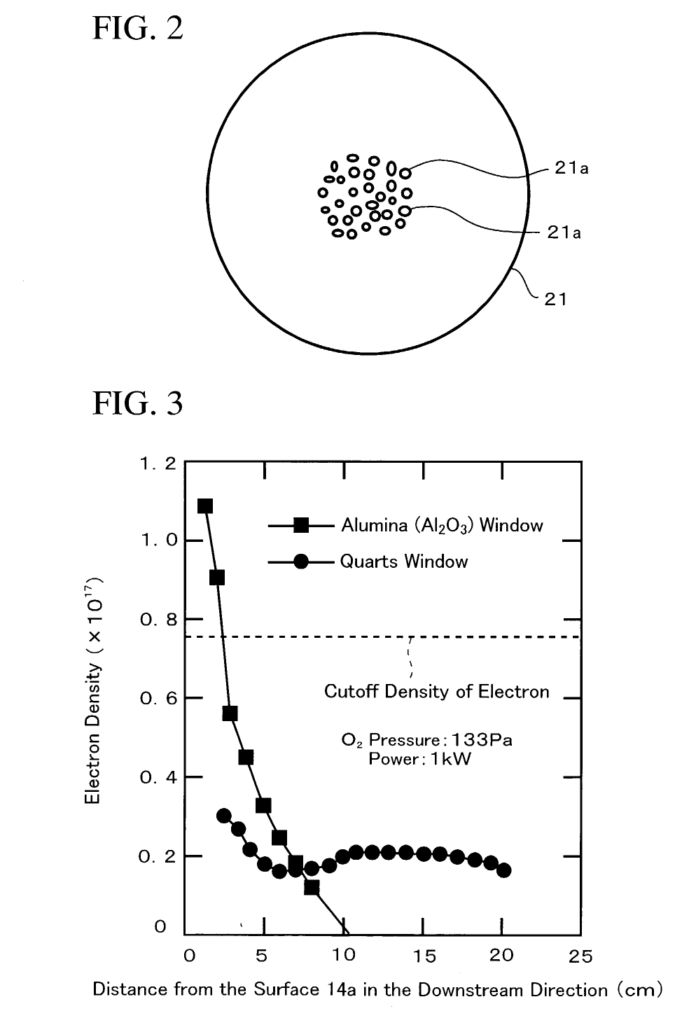

Further down in the downstream, there is provided a showerhead (gas dispersion plate) 21. FIG. 2 shows the plan view of the showerhead 21. As shown in FIG. 2, a plurality of communication holes 21a is formed in the showerhead 21. Though the communication holes 21a are shown formed only in the vicinity of center of the showerhead 21, this is intended to avoid the complicity of the drawing, and the holes 21a are actually formed near the circumference area of the showerhead 21 as well.

The diameter of the communication holes 21a is about 3 mm. However, this is not to be meant that the present invention is limited to this diameter. The diameter may be appropriately set in consideration of various factors. The preferable thickness of the shower head 21 is, but not limited to, about 1.5 times the diameter of the communication holes 21a.

Further, the distribution pattern of the communication holes 21a in a plane is not limited either. The distribution pattern may be set in such a way that the flow of the reactive gas that has passed the showerhead 21 becomes uniform on a silicon substrate (semiconductor substrate) W. Though the communication holes 21a are distributed randomly in a plane in the example depicted in FIG. 2, holes 21a may be uniformly distributed if the flow of the reactive gas is made into uniform.

Referring again to FIG. 1, there is provided a silicon compound gas supply ring 32 in the downstream of the showerhead 21. The silicon compound gas supply ring 32 communicates with a silicon compound gas supply port 38 and the inside of the reaction chamber housing 31, and serves to supply the silicon compound gas inside the housing 31. A plurality of opening portions 32a are provided in the silicon compound gas supply ring 32, from which the silicon compound gas is injected. As shown, by tilting the opening portion 32a toward the upstream and appropriately selecting its tilt angle, the uniformity of a film obtained can be improved.

Then, further down in the downstream of the silicon compound gas supply ring 32, there is provided a stage (substrate holder) 33 upon which the silicon substrate W rests. An electric heater 35 is built inside the stage 33, by which the silicon substrate W is heated to a desired temperature. The stage 33 is capable of moving vertically, and optimum process conditions can be found by adjusting the height of the silicon substrate W.

Exhaust piping 18 is provided on the sidewall of the reaction chamber housing 31, and the exhaust piping 18 is further connected to an exhaust pump 15. By opening a switching valve 13 arranged halfway the exhaust piping 18, with the exhaust pump 15 being operated, the inside of the plasma chamber housing 11 and the reaction chamber housing 31 is decompressed to a desired pressure.

In the following, description will be made while taking a case where oxygen (O₂) is used as the reactive gas and tetraethoxysilane is used as the silicon compound gas. In this case, a silicon oxide film is deposited.

In operation, the microwave is introduced onto the dielectric window 14, with the above gases having been introduced into the apparatus 10. Table 1 shows one of the examples for the conditions of the microwave and the gas.

TABLE 1

| | |
|---|---|
| Microwave | Frequency: 2.45 GHz |
| conditions | Mode: TM₀₁ |
| | Power: 1 kW |
| Gas flow rate | Oxygen (O₂): 2000 sccm |
| | Carrier gas (N₂) for bubbling: 2000 |
| | sccm |
| Pressure | 13.3 to 1330 Pa |
| Substrate | 220° C. |
| temperature | |
| Deposition rate | 220 nm/min |

Note that the pressure in Table 1 refers to the pressure in the reaction chamber housing 31.

In addition, tetraethoxysilane, liquid compound in a room temperature (20° C.), is stored in a bubbler (not shown) and supplied to the apparatus 10 by bubbling of nitrogen (N₂). The carrier gas (N₂) for bubbling refers to the flow rate of nitrogen before the bubbling.

As shown in Table 1, this embodiment uses the TM₀₁ mode microwave of the frequency of 2.45 GHz. Such microwave propagates in the waveguide 12 and is introduced onto a surface 14b of the dielectric window 14 facing upstream, in an approximately perpendicular direction. The microwave propagates further to a surface 14a, which is other surface of the dielectric window 14 facing downstream, and excites oxygen near the plane 14a. Oxygen is excited to become plasma. The plasma is highly dense and its electron density is larger than cutoff density (7.6×10¹⁶ m⁻³) determined by the microwave frequency (2.45 GHz). Therefore, the microwave does not go into the downstream of the surface 14a of dielectric window 14 and propagates in the vicinity of the surface 14a horizontally. As a result, the surface wave of the microwave is generated in the vicinity of the plane 14a of the dielectric window. The above-described oxygen plasma can be seen as the one that is excited by contacting to the surface wave. This plasma is also referred to as surface wave plasma generally.

Next, the foregoing will be verified based on the result of the experiment conducted by the inventor. In this experiment, only oxygen is supplied and tetraethoxysilane is not supplied. The pressure of oxygen inside the apparatus 10 is 133 Pa, and the power of the microwave is 1 kW.

FIG. 3 shows the electron density distribution of oxygen plasma obtained by the experiment. The abscissa in FIG. 3 denotes a distance from the surface 14a of the dielectric window 14 in the downstream direction, and the ordinate denotes the electron density of plasma.

Pay attention to a sequence shown by black circles ●. This shows the electron density of plasma when quarts is used for the dielectric window 14 and the surface wave is not created (bulk mode). In this case, since the electric density in the vicinity of the dielectric window 14 is smaller than the cutoff density, the microwave goes deep down to the downstream, and thus plasma is generated as far as 20 cm downstream.

On the other hand, pay attention to a sequence shown by black squares ▪. This shows the electron density of plasma when alumina (Al₂O₃) is used for the dielectric window 14 and the surface wave is created. As can been seen from the graph, electron density of as high as 11×10¹⁷ m⁻³ is obtained in the vicinity (about 1 cm) of the dielectric window 14. Since this electron density is larger than the cutoff density, the microwave does not go into the downstream, and thus plasma does not occur in the downstream. This is understood by the fact that the electron density rapidly attenuates toward the downstream in FIG. 3. In this example, the electron density becomes smaller than the detection limit of Langmuir probe (not shown) at about 10 cm downstream, showing that dissociated oxygen ions (equal to the number of electrons) have effectively transformed into neutral atomic oxygen. Thus, surface wave plasma has good charged particle attenuation characteristic, and is preferable for generating atomic oxygen.

Using such characteristic of surface wave plasma, the showerhead 21 (see FIG. 1) is provided at a downstream position where plasma has reached a level of detection limit. Because there is no ion having large kinetic energy at this position, the material does not scatter from the surface of the showerhead 21 due to collision with ions. Moreover, because plasma is rarely generated at this position, the showerhead 21 is prevented from being damaged by being heated by plasma.

The showerhead 21 is arranged about 5 to 20 cm downstream from the surface 14a of the dielectric window 14. However, the present invention is not limited to this distance. What is important is to restrict generation of plasma in the downstream region by using surface wave plasma and to provide the showerhead 21 at a downstream position where plasma is rarely generated.

The showerhead 21 does not only make the flow of the reactive gas uniform. It has been clarified that the charged particles (ions, electrons, or the like) in the reactive gas are neutralized to be removed when the reactive gas passes through the showerhead 21. Since the charged particles are removed, charge-up, that could occur when the charged particles reach on the silicon substrate W, can be prevented.

Material of the showerhead 21 is not particularly limited. The foregoing advantages can be obtained when any of conductor, semiconductor, and insulator is employed for the showerhead 21. An example of conductor is aluminum.

Furthermore, the showerhead 21 may be grounded or in an electrically floating state. The foregoing advantages can be obtained in either case.

Incidentally, when the downstream of the showerhead 21 is observed from an observation port 36 with surface wave plasma being generated in the upstream, light emission associated with state transition of oxygen atoms was below a measurement limit. This means that atomic oxygen in the downstream of the showerhead 21 is almost in their ground state. According to this result, it has been found out that the energy of the atomic oxygen decreases to near the ground state (O (3P)) by exposing oxygen gas to the surface wave to transform it into atomic oxygen and passing it through the showerhead 21.

Atomic oxygen contributes to reaction with tetraethoxysilane and has conventionally been obtained by thermally decomposing ozone at the temperature of about 400° C. Since the present invention generates atomic oxygen not by thermal decomposition but by surface wave plasma, the deposition temperature can be set lower (about 220° C.) than that of thermal decomposition, and occurrence of hillock and the like can be restricted.

Moreover, since the showerhead 21 reduces the energy of atomic oxygen, the secondary electrons that could be generated when atomic oxygen of high energy reaches the silicon substrate W reduce, which in turn makes the silicon substrate W hard to be charged up, and occurrence of gate breakage or the like can be restricted.

Table 2 shows such advantages.

TABLE 2

| | | Ozone | Plasma |
|---|---|---|---|
| | Present | growth | growth |
| | invention | (Prior art) | (Prior art) |
| Deposition | 220° C. | 400° C. | 210° C. |
| temperature (° C.) | | | |
| Number of gate | No | No | 5/200 |
| breakage* | | | |
| Hillock occurrence | No | Yes | No |

*Number of evaluation: 200 pieces
In ‘the present invention’ of Table 2, the silicon oxide film was deposited according to the conditions of Table 1.

In evaluation of ‘the number of gate breakage’, 4 evaluation wafers were used. 50 pieces of samples, each consist of a pair of MOS transistors and aluminum wirings, are formed on each evaluation wafer. Accordingly, the total number of samples is 200 pieces (=4×50).

As a result, the gate insulating film of the MOS transistor was not broken in the present invention. On the contrary, in the plasma growth according to the prior art, plasma caused charge-up in the aluminum wirings, and the gate insulating film was broken in 5 samples.

On the other hand, 4 evaluation wafers different from the foregoing were used in evaluation of ‘the hillock occurrence’ in Table 2. A large number of long and narrow aluminum wiring patterns are formed on each evaluation wafer.

As a result, the hillock occurred on the aluminum wirings in the thermal reaction (ozone growth) between ozone and tetraethoxysilane due to the high deposition temperature (400° C.) whereas the hillock did not occur in the present invention.

Further, as shown in FIG. 1, since the silicon compound gas supply ring 32 is positioned in the downstream of the showerhead 21, oxygen and tetraethoxysilane react in the downstream of the showerhead 21, but do not react in the upstream of the showerhead 21. Therefore, inconvenience that the reaction product deposits on the showerhead 21 does not occur in the present invention.

Furthermore, as shown in Table 1, the deposition rate of this embodiment is 220 nm/min, which is about the same value of the ozone growth (growth temperature 400° C.) used for comparison in Table 2. As such, reduction of the deposition rate, which has been observed in the case of ozone growth under a low temperature, does not occur in this embodiment. Accordingly, the deposition temperature can be reduced while preventing the reduction of the deposition rate.

The silicon compound gas is not limited to tetraethoxysilane. In the present invention, the following alkoxysilane or inorganic silane can be used.

TABLE 3

| | |
|---|---|
| Alkoxysilane | Tetramethoxysilane (Si(OCH₃)₄) |
| | Tetraethoxysilane (Si(OC₂H₅)₄) |
| | Tetrapropoxysilane (Si(OC₃H₇)₄) |
| | Tetrabutoxysilane (Si(OC₄H₉)₄) |
| | Trimethoxysilane (SiH(OCH₃)₃) |
| | Triethoxysilane (SiH(OC₂H₅)₃) |
| Inorganic silane | Monosilane (SiH₄) |
| | Disilane (Si₂H₆) |
| | Trisilane (Si₃H₈) |

In Table 3, those that are liquid in a room temperature are supplied by decompression without bubbling or bubbling by nitrogen (N₂) or the like.

Further, the reactive gas is not limited to oxygen. Gases shown in Table 4 can be used other than oxygen.

TABLE 4

| | |
|---|---|
| Reactive gas | Oxygen (O₂) |
| | Hydrogen peroxide (H₂O₂) |
| | Steam (H₂O) |
| | Nitric oxide (NO) |
| | Nitrogen monoxide (N₂O) |
| | Nitrogen dioxide (NO₂) |
| | Nitrogen trioxide (NO₃) |

Hydrogen peroxide (H₂O₂) in Table 4 is liquid in the room temperature, and it is supplied by bubbling of nitrogen (N₂).

Arbitrarily combining at least one of the reactive gases in Table 4 or gas mixture thereof, and one of the foregoing silicon compound gases causes deposition of the silicon oxide film (silicon-containing film). Note that the silicon oxide film described in the present invention refers to a film containing at least oxygen and silicon, and composition ratio of oxygen and silicon is not limited.

Nitrogen (N₂) may be added to oxygen (O₂) of Table 4 in some cases. It has been clarified that adding oxygen promotes dissociation of oxygen (O₂) to promote deposition. An example of an added amount of nitrogen (N₂) is about 10% of oxygen (O₂) in flow rate. Similar advantage is expected by adding nitrogen (N₂) to oxidizing gas other than oxygen (O₂).

Furthermore, inert gas may be added to the reactive gas or the silicon compound gas. The inert gas in this case is any one of helium (He), argon (Ar) and neon (Ne), and gas mixture thereof.

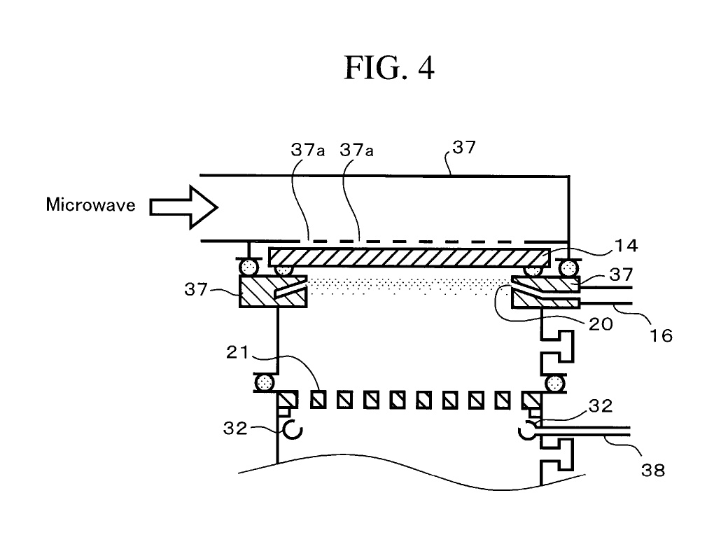

Still further, the introduction method of the microwave is not limited to the foregoing. As shown in FIG. 4, the waveguide 37 to which a plurality of the slits 37a are provided may be employed. In this case, the microwave is introduced in a horizontal direction and introduced onto the dielectric window 14 via the slits 37.

### EXAMPLE

Next, examples of the present invention will be described.

In this example, the present invention is applied to a process for a DRAM.

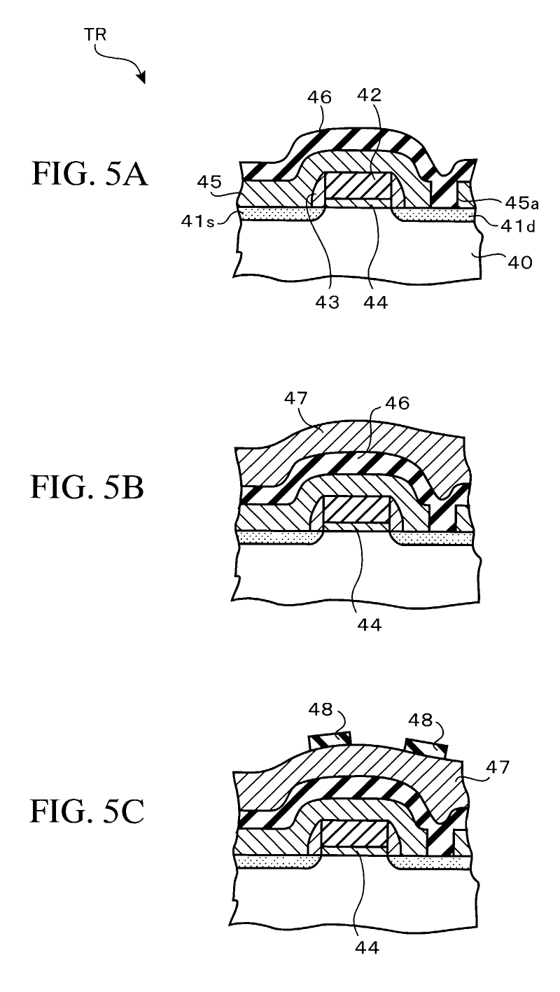

First, a transfer gate transistor TR of the DRAM is prepared as shown in FIG. 5A. The transistor TR is formed on a p-type silicon substrate 40, and has source region 41s and a drain region 41d of an n-type. The source region 41s is electrically connected to a memory capacitor (not shown).

Then, a gate insulating film 44 formed of the silicon oxide film or the like is formed on the p-type silicon substrate 40 at the area of a channel region. Moreover, a word line 42 formed of polysilicon or the like is formed on the gate insulating film 44, and a sidewall insulating film 43 formed of silicon nitride film or the like is formed on its sides.

In the drawing, reference numeral 45 denotes the insulating film such as the silicon oxide film. A bit line 46 (wiring layer) formed of aluminum is formed on the insulating film 45, and the bit line 46 is electrically connected with the drain region 41d via a contact hole 45a of the insulating film 45. The above-described structure can be fabricated by a known technology in the art.

Next, as shown in FIG. 5B, an interlayer insulating film 47 is formed on the bit line 46. The present invention is applied to the interlayer insulating film 47. Its deposition conditions are as shown in Table 1, and the film thickness can be controlled as desired by adjusting deposition time.

According to the present invention, the bit line 46 is not charged up when forming the interlayer insulating film 47. Therefore, the gate insulating film 44 of a thin film thickness is not broken by the antenna effect of the bit line 46. In addition, hillock does not occur on the bit line 46 formed of aluminum because the deposition temperature of the interlayer insulating film 47 can be set to a low.

Next, as shown in FIG. 5C, an aluminum film is formed on the interlayer insulating film 47 and patterning is performed thereto, and thus forming a second word line 48. Then, the manufacturing process of the DRAM completes after a predetermined process is performed.

Although the present invention is applied for the transfer gate transistor of the DRAM in this example, the present invention is not limited to this example. Advantages similar to this example can be obtained by applying the present invention to the manufacturing process of other devices using a MOS transistor.

Furthermore, the present invention can be preferably applied to the process that requires reduction of charge-up in the substrate or reduction of the deposition temperature even if the MOS transistor is not formed. For example, it is preferable to deposit the silicon-containing film by the present invention as a mask for etching on a low dielectric constant film, whose heat resistance is believed to be poor. Since such a silicon-containing film is deposited under the low temperature, heat does not deteriorate the low dielectric constant film.

Although the present invention has been described in detail, the present invention is not limited to the above embodiment. For example, although the silicon substrate is used in the foregoing, a quarts substrate may be used in the alternative. Since the quarts substrate has poor heat resistance and requires deposition process under the low temperature, the present invention capable of depositing under the low temperature is preferably applied. Further, the present invention can also be applied to damascene process, which is preferable for forming copper wirings.

The present invention can be variously varied and executed within a scope of its spirit.

As described above, in the deposition method according to the present invention, reactive gas is made to pass through the communication holes and guided toward the downstream of the communication holes after the gas is exposed to the surface wave of the microwave. According to this, deposition can be performed under the lower temperature than the conventional method, and charge-up of the substrate can be prevented. Therefore, occurrence of hillock on the wiring layer and breakage of the gate insulating film of a transistor can be prevented.

In the deposition apparatus according to the present invention, the gas dispersion plate is provided at a distance from the dielectric window, in order to avoid the influence of surface wave plasma generated near the dielectric window. Since the surface wave plasma attenuates rapidly toward the downstream, arranging the gas dispersion plate as described above can prevent the dispersion plate from suffering damage by plasma.

Furthermore, by making the reactive gas pass through the gas dispersion plate, the charged particles remaining in the reactive gas can be approximately completely removed and the energy of the atomic reactive gas can be reduced near its ground state. This can prevent the substrate from charged up.

What is claimed is:

1. A deposition method comprising:
after exposing a reactive gas to a surface wave of a microwave, guiding the reactive gas to a downstream of a communication hole by making the reactive gas to pass through the communication hole, and making the reactive gas to react with a silicon compound gas at the downstream to form a silicon-containing film on a substrate arranged at the downstream.

2. The deposition method according to claim 1, wherein, by introducing the microwave onto one surface of a dielectric window, the surface wave generates in the vicinity of other surface of the dielectric window

3. The deposition method according to claim 1, wherein
an electron density of the reactive gas in the vicinity of the surface wave is larger than 7.6×10¹⁶ m³.

4. The deposition method according to claim 1, wherein
each of a plurality of openings formed in a gas dispersion plate is used as the communication hole.

5. The deposition method according to claim 4, wherein
a pressure of atmosphere, which contains the reactive gas and the silicon compound gas, is about 13.3 to 1330 pascal (Pa) in the downstream, and
the gas dispersion plate is provided at a distance of about 5 to 20 cm from the other surface of the dielectric window in the downstream thereof.

6. The deposition method according to claim 1, wherein
any one of alkoxysilane and inorganic silane is used as the silicon compound gas.

7. The deposition method according to claim 6, wherein
any one of tetramethoxysilane (Si(OCH₃)₄), tetraethoxysilane (Si(OC₂H₅)₄), tetrapropoxysilane (Si(OC₃H₇)₄), tetrabutoxysilane (Si(OC₄H₉)₄), trimethoxysilane (SiH(OCH₃)₃), and triethoxysilane (SiH(OC₂H₅)₃) is used as the alkoxysilane.

8. The deposition method according to claim 6, wherein
any one of monosilane (SiH₄), disilane (Si₂H₆), and trisilane (Si₃H₈) is used as the inorganic silane.

9. The deposition method according to claim 6, wherein
any one of oxygen (O₂), hydrogen peroxide (H₂O₂), steam (H₂O), nitric oxide (NO), nitrogen monoxide (N₂O), nitrogen dioxide (NO₂), nitrogen trioxide (NO₃), and gas mixture thereof is used as the reactive gas.

10. The deposition method according to claim 6, wherein
oxygen (O₂), to which nitrogen (N₂) is added, is used as the reactive gas.

11. The deposition method according to claim 6, wherein
inert gas is added to any one of the reactive gas and the silicon compound gas.

12. The deposition method according to claim 11, wherein
the inert gas is the one selected from the group consisting of helium (He), argon (Ar), neon (Ne), and gas mixture thereof.

13. The deposition method according to claim 1, wherein
a semiconductor substrate is used as the substrate.

14. The deposition method according to claim 1, wherein
a glass substrate is used as said substrate.

15. A semiconductor device, comprising:
the silicon-containing film deposited by the deposition method according to claim 1.

16. A deposition apparatus, comprising:
a dielectric window having two principal surfaces, where a microwave being introduced onto one of the two principal surfaces;
a gas dispersion plate that is provided at a distance from other principal surface of the dielectric window and has a plurality of communication holes;
a substrate holder provided in downstream of the gas dispersion plate;
a reactive gas supply port that is in communication with a space between the substrate holder and the other principal surface of the dielectric window; and
a silicon compound gas supply port that is in communication with the space.

17. The deposition apparatus according to claim 16, wherein
the reactive gas supply port is in communication with upstream of the gas dispersion plate, and
the silicon compound gas supply port is in communication with downstream of the gas dispersion plate.

18. The deposition apparatus according to claim 16, wherein
the gas dispersion plate is provided at a distance of about 5 to 20 cm from the other surface of the dielectric window in the downstream thereof.

19. The deposition apparatus according to claim 16, wherein
any one of alkoxysilane and inorganic silane is supplied from the silicon compound gas supply port.

20. The deposition apparatus according to claim 19, wherein
the alkoxysilane is the one selected from the group consisting of tetramethoxysilane (Si(OCH₃)₄), tetraethoxysilane (Si(OC₂H₅)₄), tetrapropoxysilane (Si(OC₃H₇)₄), tetrabutoxysilane (Si(OC₄H₉)₄), trimethoxysilane (SiH (OCH₃)₃), and triethoxysilane (SiH(OC₂H₅)₃).

21. The deposition apparatus according to claim 19, wherein
the inorganic silane is the one selected from the group consisting of monosilane (SiH₄), disilane (Si₂H₆), and trisilane (Si₃H₈).

22. The deposition apparatus according to claim 16, wherein
any one of oxygen (O₂), hydrogen peroxide (H₂O₂), steam (H₂O), nitric oxide (NO), nitrogen monoxide (N₂O), nitrogen dioxide (NO₂), nitrogen trioxide (NO₃), and gas mixture thereof is supplied from the reactive gas supply port.

23. The deposition apparatus according to claim 16, wherein
oxygen (O₂), to which nitrogen (N₂) is added, is supplied from said reactive gas supply port.

24. The deposition apparatus according to claim 19, wherein
inert gas is further supplied from any one of the silicon compound supply port and the reactive gas supply port.

25. The deposition apparatus according to claim 24, wherein
the inert gas is the one selected from the group consisting of helium (He), argon (Ar) neon (Ne), and gas mixture thereof.
